(19) United States
(12) Patent Application Publication
(10) Pub. No.: US 2026/0081400 A1
(43) Pub. Date: Mar. 19, 2026

(54) MULTI-WAVELENGTH LASER

(71) Applicant: Lumentum Operations LLC, San Jose, CA (US)

(72) Inventor: Kouji NAKAHARA, Tokyo (JP)

(21) Appl. No.: 19/065,733

(22) Filed: Feb. 27, 2025

(30) Foreign Application Priority Data
Sep. 17, 2024 (JP) 2024160009
Oct. 25, 2024 (JP) 2024188354

(51) Int. Cl. H01S 5/12; H01S 5/10

(52) U.S. Cl. CPC H01S 5/124; H01S 5/1096

(57) ABSTRACT

A multi-wavelength laser includes an active layer and a diffraction grating layer that includes a front diffraction grating region, a rear diffraction grating region, and a phase shift region between the front diffraction grating region and the rear diffraction grating region. The front diffraction grating region includes one or more grating regions. Each of the one or more grating regions includes a series of unit structures that are different from each other. The rear diffraction grating region has the same structure as a structure of the front diffraction grating region.

### CROSS-REFERENCE TO RELATED APPLICATION

This patent application claims priority to Japan Patent Application No. JP2024-188354, filed on Oct. 25, 2024, and Japan Patent Application No. JP2024-160009, filed on Sep. 17, 2024. The disclosures of the prior Applications are considered part of and are incorporated by reference into this patent application.

### TECHNICAL FIELD

The present disclosure relates generally to a multi-wavelength laser.

### BACKGROUND

The Internet is continuously evolving as an infrastructure of modern society. Optical communication, which is high in speed and is excellent in long-distance communication, enables many parts of Internet communication. Along with a continuous increase in Internet traffic, an increase in communication capacity has become a pressing issue. In order to cope with the increase in communication capacity, for example, a wavelength division multiplexing (WDM) technology can be used.

### SUMMARY

In optical communication, using a plurality of wavelengths, as typified by WDM communication, often requires a plurality of light sources corresponding to a number of the plurality of wavelengths. For example, in a case of a semiconductor laser including a light source that oscillates at a single wavelength, a plurality of semiconductor lasers having different oscillation wavelengths are required. Meanwhile, a wavelength-tunable laser capable of tuning the oscillation wavelength is also used. The wavelength-tunable laser can tune the wavelength in a wide range, and hence there is not a need to prepare semiconductor lasers having different wavelengths. However, the number of wavelength-tunable lasers required is equal to the number of wavelengths used in WDM communication. Further, the wavelength-tunable laser sets the wavelength, and hence has a more complicated structure as compared to a laser that oscillates only at a single wavelength, resulting in a disadvantage in terms of cost.

At least one implementation of the present invention provides a multi-wavelength laser in which one semiconductor laser oscillates at a plurality of wavelengths.

In some implementations, a multi-wavelength laser includes: an active layer; and a diffraction grating layer including a front diffraction grating region, a rear diffraction grating region, and a phase shift region between the front diffraction grating region and the rear diffraction grating region, wherein the front diffraction grating region includes one or more grating regions, wherein each of the one or more grating regions includes a series of unit structures that are different from each other, and wherein the rear diffraction grating region has the same structure as a structure of the front diffraction grating region.

### BRIEF DESCRIPTION OF THE DRAWINGS

FIG. 1 is a top view of a multi-wavelength laser according to a first example implementation of the present invention.

FIG. 2 is a schematic cross-sectional view taken along the line II-II of the multi-wavelength laser illustrated in FIG. 1.

FIG. 3 is a schematic cross-sectional view of a multi-wavelength laser according to Modification Example 1 of the first example implementation.

FIG. 4 is a wavelength spectrum of the multi-wavelength laser according to Modification Example 1 of the first example implementation.

FIG. 5 is a schematic cross-sectional view of a multi-wavelength laser according to Modification Example 2 of the first example implementation.

FIG. 6 is a top view of a multi-wavelength laser according to a second example implementation of the present invention.

FIG. 7 is a schematic cross-sectional view taken along the line VII-VII of the multi-wavelength laser illustrated in FIG. 6.

FIG. 8 is a top view of a multi-wavelength laser according to a third example implementation of the present invention.

FIG. 9 is a top view of a multi-wavelength laser according to a fourth example implementation of the present invention.

FIG. 10 is a schematic cross-sectional view taken along the line X-X of the multi-wavelength laser illustrated in FIG. 9.

FIG. 11 is a top view of a multi-wavelength laser according to a fifth example implementation of the present invention.

FIG. 12 is a schematic cross-sectional view taken along the line XII-XII of the multi-wavelength laser illustrated in FIG. 11.

### DETAILED DESCRIPTION

A specific and detailed description is given below on example implementations of the present invention with reference to the drawings. Members denoted by the same reference symbol throughout the drawings have the same or an equivalent function, and a repetitive description on the members is omitted. Note that sizes of graphics are not always to scale.

The following detailed description of example implementations refers to the accompanying drawings. The same reference numbers in different drawings may identify the same or similar elements.

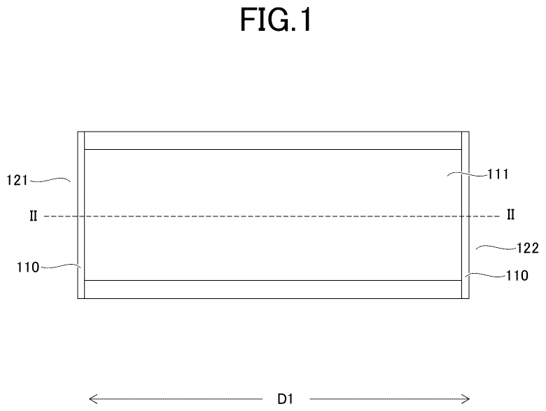

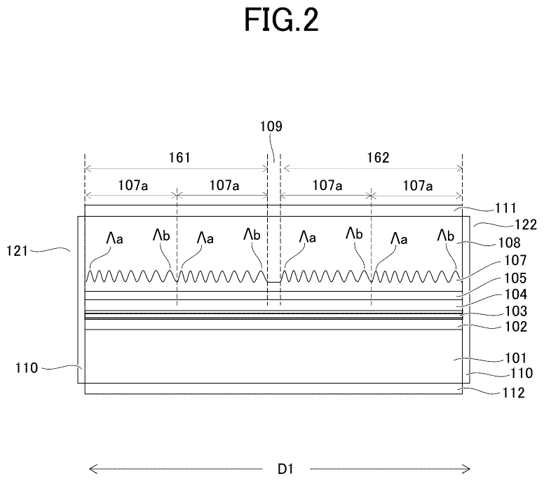

FIG. 1 is a top view of a multi-wavelength laser according to a first example implementation of the present invention. FIG. 2 is a cross-sectional view for schematically illustrating a cross section taken along the line II-II of FIG. 1.

The multi-wavelength laser includes a semiconductor multilayer. The semiconductor may be obtained by growing, on a substrate 101, a first-conductivity-type optical confinement layer 102, an active layer 103, a second-conductivity-type optical confinement layer 104, a second-conductivity-type spacer layer 105, a second-conductivity-type diffraction grating layer 107, and a second-conductivity-type cladding layer 108 in the stated order. In this case, the first conductivity type may be an “n” type, and the second conductivity type may be a “p” type, but the conductivity types may be opposite. A back surface electrode 112 may be arranged on a back surface of the substrate 101, and a front surface electrode 111 may be arranged on the second-conductivity-type cladding layer 108 side. A contact layer may be arranged between the front surface electrode 111 and the second-conductivity-type cladding layer 108. In this case, a direction in which the active layer 103 and the diffraction grating layer 107 extend is referred to as “first direction D1.” The first direction D1 may be also referred to as “optical axis direction.” A first facet 121 and a second facet 122 may be respectively arranged on both sides in the first direction D1, and an anti-reflection film 110 may be formed on each of the first facet 121 and the second facet 122. The first facet 121 is referred to as “rear facet,” and the second facet 122 is referred to as “front facet.” The “front” and the “rear” referred to here may be names to be used for the sake of convenience in the description, and the “front” and the “rear” may be reversed. The anti-reflection film 110 may be formed so as to function as an anti-reflection film for a wavelength region at which multi-wavelength laser according to the first example implementation oscillates (all wavelengths from the minimum oscillation wavelength to the maximum oscillation wavelength).

In this case, the substrate 101, the spacer layer 105, and the second-conductivity-type cladding layer 108 are comprising InP. The two optical confinement layers 102 and 104, the active layer 103, and the diffraction grating layer 107 comprise InGaAsP or InGaAlAs. Those materials are merely examples. The active layer 103 is, for example, a multiple quantum well (MQW) layer to which a distortion is applied. The diffraction grating layer 107 includes a diffraction grating structure by forming recesses and protrusions at an interface between the second-conductivity-type cladding layer 108 and the diffraction grating layer 107. The recesses and protrusions may be formed at an interface between the spacer layer 105 and the diffraction grating layer 107. In this case, the semiconductor multilayer has, for example, a composition wavelength that is set so as to achieve oscillation at a 1,300-nm band, but the present invention is not limited thereto. Oscillation may be achieved in other wavelength bands such as a 1,550-nm band.

A cross section taken along a direction perpendicular to the optical axis has, for example, a BH structure in which semiconductor layers are arranged on both sides of a mesa structure including the active layer 103, or a ridge structure in which one or more layers above the active layer 103 (for example, the second-conductivity-type cladding layer 108) include a mesa structure.

The diffraction grating layer 107 may include a first diffraction grating region 161, a second diffraction grating region 162, and a phase shift region 109 arranged between the first diffraction grating region 161 and the second diffraction grating region 162. The phase shift region 109 causes a λ/4 phase shift. In this case, the first diffraction grating region 161 may be arranged between the phase shift region 109 and the rear facet (first facet 121), and is also referred to as “rear diffraction grating region.” The second diffraction grating region 162 may be arranged between the phase shift region 109 and the front facet (second facet 122), and is also referred to as “front diffraction grating region.” Each of the front diffraction grating region and the rear diffraction grating region may be formed of a grating region 107a. In this case, each of the two regions is formed of two grating regions 107a. Each of the grating regions 107a may include a series of unit structures. Each of the unit structures in the first example implementation may be a diffraction grating structure corresponding to one period. A plurality of unit structures form the grating region 107a. In the first example implementation, in the grating region 107a, the periods of the respective unit structures gradually increase from a first unit structure at one end toward a second unit structure at another end. Specifically, the grating region 107a may include the first unit structure having the shortest diffraction grating period Λa at a left end on the first facet 121 side, and may include the second unit structure having the longest diffraction grating period Λb at a right end on the second facet 122 side. Periods of a plurality of unit structures arranged between the first unit structure and the second unit structure gradually increase from the diffraction grating period Λa to the diffraction grating period Λb from the left end on the first facet 121 side toward the right end on the second facet 122 side. In other words, the grating region 107a may have a chirped diffraction grating structure. The diffraction grating period Λa and the diffraction grating period Λb may be reversed. That is, in the grating region 107a, the periods of the respective unit structures may gradually decrease from the first unit structure at one end toward the second unit structure at another end. When the periods of the respective unit structures are caused to gradually decrease, in all of the grating regions 107a as well, the periods of the respective unit structures may be similarly caused to gradually decrease from the first unit structure toward the second unit structure.

The diffraction grating period Λa and the diffraction grating period Λb may have periods corresponding to the minimum wavelength and the maximum wavelength, respectively, of multi-wavelength oscillation. That is, when an effective refractive index of a waveguide of a laser is represented by n_{eff}, a minimum oscillation wavelength λₐ and a maximum oscillation wavelength λ_{b} are represented as follows:

$${λ}_{a} = 2 {n}_{eff} {Λ}_{a} ; and \qquad ( 1 )$$

$${λ}_{b} = 2 {n}_{eff} {Λ}_{b} . \qquad ( 2 )$$

In an example case, the oscillation spectral intensities at both ends are decreased, and hence, with slight margins, the diffraction grating period Λa is set to be smaller than the diffraction grating period Λa obtained by Expression (1) and the diffraction grating period Λb is set to be larger than the diffraction grating period Λb obtained by Expression (2). Further, a wavelength interval Δλₛ between wavelengths under multi-wavelength oscillation is determined based on the length of the grating region 107a in the first direction D1. When the length of the grating region 107a in the first direction D1 is represented by Lₛ and a center wavelength, that is, an average of λₐ and λ_{b} is represented by λₒ, the wavelength interval Δλₛ is represented as follows.

$$Δ {λ}_{s} = \frac{{λ}_{0}^{2}}{2 {n}_{eff} {L}_{s}} \qquad ( 3 )$$

In this case, n_{eff} is, to be accurate, a group refractive index ng obtained in consideration of refractive index dispersion. In the present invention, after careful consideration and investigation, it has been found that, when the first diffraction grating region 161 and the second diffraction grating region 162 each formed of two grating regions 107a are provided, and the phase shift region for causing a λ/4 phase shift is inserted between the first diffraction grating region 161 and the second diffraction grating region 162, multi-wavelength oscillation having regular intervals can be obtained. Moreover, with the anti-reflection film being formed on each of the first facet 121 and the second facet 122, the side-mode suppression ratio can be improved, and undesired wavelength oscillation has successfully been suppressed. The symbol λ in the λ/4 phase shift represents an average wavelength (λₒ) of λₐ and λ_{b}.

In this case, two grating regions 107a are arranged in each of the first diffraction grating region 161 and the second diffraction grating region 162 sandwiching the phase shift region 109, but the present invention is not limited thereto. Three or more grating regions 107a may be arranged in each of the first diffraction grating region 161 and the second diffraction grating region 162 (six grating regions 107a in total). When a plurality of grating regions 107a are arranged in the first diffraction grating region 161 and/or the second diffraction grating region 162, those plurality of grating regions 107a may be adjacent to each other without interposing other structures therebetween.

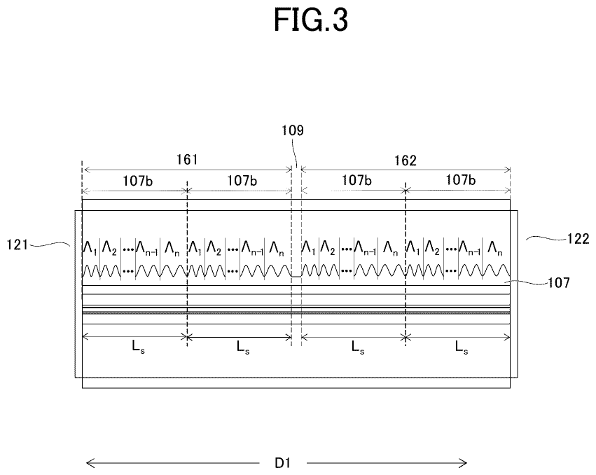

FIG. 3 is a schematic cross-sectional view taken along the optical axis of a multi-wavelength laser according to Modification Example 1 of the first example implementation. The difference from FIG. 2 for illustrating the first example implementation resides in a grating region 107b. When the chirped diffraction grating structure illustrated in the first example implementation is formed, an electron beam lithography device is often used. Some types of this device have difficulty in forming a diffraction grating having a period that gradually increases or gradually decreases. In such a case, as in Modification Example 1, a grating structure having a period that changes stepwise, that is, a grating structure in which each unit structure is formed of a series of sub-unit structures having the same period may be used.

The grating region 107b changes so that the diffraction grating period sequentially increases at a plurality of stages from a minimum diffraction grating period Λ₁ toward a maximum diffraction grating period Λₙ. That is, a series of unit structures include, as illustrated in FIG. 3, a unit structure formed of two sub-unit structures that are continuous in the first direction D1 and have the minimum diffraction grating period Λ₁, a unit structure formed of two sub-unit structures that are continuous and have a period slightly larger in diffraction grating period than Λ₁, and a unit structure formed of two sub-unit structures that are continuous and have a diffraction grating period obtained by further increasing the diffraction grating period, which are arranged side by side, and finally include a unit structure formed of two sub-unit structures that are continuous and have the maximum diffraction grating period Λₙ. In Modification Example 1, for the sake of easiness in illustration, a case in which each unit structure is formed of two sub-unit structures is exemplified, but each unit structure may be formed of three or more sub-unit structures. That is, each unit structure may be formed of a plurality of sub-unit structures. Similarly to the first example implementation, four grating regions 107b are arranged side by side in the optical axis direction, and the phase shift region 109 is arranged between the first diffraction grating region 161 and the second diffraction grating region 162. Also with this structure, similarly to the first embodiment, a multi-wavelength laser for simultaneously oscillating at a plurality of wavelengths can be obtained.

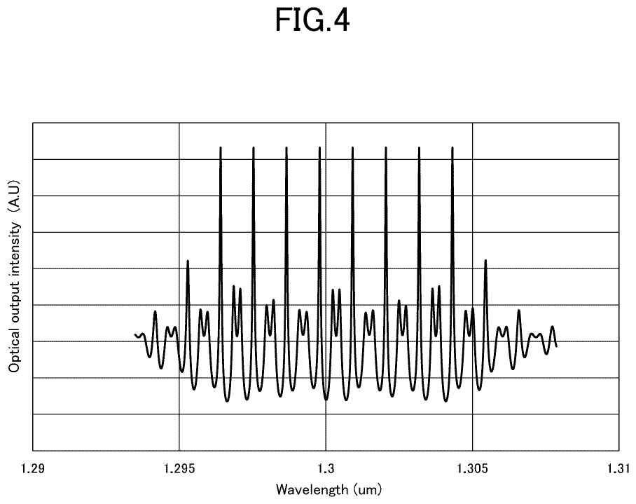

FIG. 4 is an example of a wavelength spectrum of the multi-wavelength laser according to Modification Example 1. In this case, Λ₁=200.999 nm and Λₙ=202.927 nm are satisfied, and the diffraction grating period has been changed so as to sequentially increase at twenty stages within this range. When the wavelength interval is set to 1.1285 nm corresponding to an interval of 200 GHz, Lₛ is 232.76 μm. In this case, n_{eff} of 3.22 has been used. The diffraction grating layer 107 is formed of four grating regions 107b, and hence the resonator length of the entire multi-wavelength laser is 931 μm. The resonator length includes the length of the phase shift region 109. In this case, the phase shift region 109 is a structure in which two continuous recesses are arranged side by side, and the length of the phase shift region 109 in the first direction D1 is very short. As shown in FIG. 4, with the multi-wavelength laser according to Modification Example 1, an oscillation spectrum of a plurality of wavelengths can be obtained. An interval of the wavelengths is about 1.1 nm. Among those, light beams of eight wavelengths positioned at the middle are simultaneously oscillated at substantially the same optical output intensity. When the oscillation light including those eight wavelengths is split with use of a wavelength de-multiplexer, one semiconductor laser can be used as eight light sources for WDM communication. Further, the oscillation light can also be used as it is without being split. For example, when the multi-wavelength light is combined with a plurality of ring modulators, modulated light beams can be individually generated for every wavelength without polarization.

The grating region 107a in the first example implementation and the grating region 107b in Modification Example 1 are each a diffraction grating structure that changes from a first diffraction grating period to a second diffraction grating period. In the description above, the first diffraction grating period is a diffraction grating period corresponding to the minimum wavelength and the second diffraction grating period is a diffraction grating period corresponding to the maximum wavelength, but the opposite may be applied. It should be noted that, even in the opposite case, the grating structures arranged at the front and the rear (both ends) of the phase shift region 109 may be the same. That is, when the grating region 107a and 107b in the first diffraction grating region 161 is formed to have a series of unit structures that change from the diffraction grating period corresponding to the maximum wavelength to the diffraction grating period corresponding to the minimum wavelength, the grating region 107a and 107b in the second diffraction grating region 162 is also formed to have a series of unit structures that change from the diffraction grating period corresponding to the maximum wavelength to the diffraction grating period corresponding to the minimum wavelength. Further, when a plurality of grating regions 107a and 107b are arranged in each of the first diffraction grating region 161 and the second diffraction grating region 162, all of those plurality of grating regions 107a and 107b are each formed of a series of unit structures that change in diffraction grating period in the same direction.

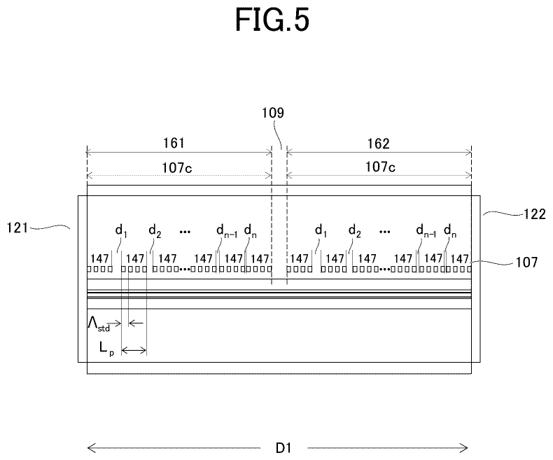

FIG. 5 is a schematic cross-sectional view taken along the optical axis of a multi-wavelength laser according to Modification Example 2 of the first example implementation. The difference from the first example implementation and Modification Example 1 resides only in the diffraction grating layer 107 and a grating region 107c. The diffraction grating structure in Modification Example 2 is not the recesses and protrusions formed on the surface of the diffraction grating layer 107, but a so-called floating-type diffraction grating structure arranged in the spacer layer 105 and the second-conductivity-type cladding layer 108. Further, in the first embodiment or Modification Example 1, the chirped diffraction grating structure or the stepwise chirped diffraction grating structure in which the diffraction grating period changes stepwise has been described, but, depending on the electron beam lithography device, the lithography time may increase when the diffraction grating period is changed, and the lithography program may become huge. In Modification Example 2, without changing the diffraction grating period, a plurality of phase shift portions having different phase shift amounts are arranged. Thus, the grating region 107c with which the same effect as that of the first example implementation and Modification Example 1 can be obtained is provided.

The stepwise chirped diffraction grating structure described in Modification Example 1 includes “n” diffraction grating periods Λₛ from the diffraction grating period Λ₁ corresponding to the minimum wavelength to the diffraction grating period Λₙ corresponding to the maximum wavelength. When an average value of Λ₁ and Λₙ is represented by Λ_{std}, a phase shift amount Φₛ is represented as follows.

$${Φ}_{s} = 2 {L}_{p} \frac{π {Λ}_{s}}{{Λ}_{std}} \qquad ( 4 )$$

In Expression (4), Lₚ represents the length for which the diffraction grating structure having a period Λ_{std} continues. In the following, a region having this uniform diffraction grating structure is referred to as “uniform grating structure 147.” The phase shift amount Φₛ is obtained for each diffraction grating period Λₛ based on Expression (4), and a length of a phase shift portion dₛ corresponding to this phase shift amount Φₛ is determined. Then, from the first facet 121 side toward the second facet 122 side, a unit structure formed of the uniform grating structure 147 and a phase shift portion d₁, a unit structure formed of the uniform grating structure 147 and a phase shift portion d₂, . . . , a unit structure formed of the uniform grating structure 147 and a phase shift portion dₙ₋₁, and a unit structure formed of the uniform grating structure 147 and a phase shift portion dₙ are arranged. Finally, the uniform grating structure 147 is arranged. A region formed of those series of unit structures becomes the grating region 107c corresponding to the grating region 107b in Modification Example 1. Each phase shift amount Φₛ of the phase shift portion “d” is not constant, and is a value corresponding to each of the “n” diffraction grating periods included in the stepwise chirped diffraction grating structure described in Modification Example 1. Accordingly, the length of each phase shift portion “d” basically varies. The uniform diffraction grating structure is a structure in which a high refractive index layer and a low refractive index layer are alternately arranged side by side. In FIG. 5, a region indicated by a rectangle represents the high refractive index layer, and a region sandwiched between two rectangles represents the low refractive index layer. The uniform grating structure 147 is a structure in which, assuming that one high refractive index layer and one low refractive index layer form one set, the sets may be successively arranged side by side at the same interval (same period). Strictly speaking, the length Lₚ of the uniform grating structure 147 is an interval that starts from the high refractive index layer and ends at the low refractive index layer. However, the phase shift portion “d” is adjacent to the region of the last low refractive index layer. Thus, in terms of manufacture, the phase shift amount may be adjusted by the interval between the last high refractive index layer of the uniform grating structure 147 and the first high refractive index layer of the next uniform grating structure 147. Accordingly, for the sake of convenience, FIG. 5 shows the interval between the high refractive index layer and the high refractive index layer as Lₚ. The grating region 107b in Modification Example 1 and the grating region 107c in Modification Example 2 have different structures, but have equivalent functions from the viewpoint of reflection of light, and muti-wavelength oscillation can be performed with one semiconductor laser.

In the multi-wavelength laser according to Modification Example 2, one grating region 107c is disposed in each of the first diffraction grating region 161 and the second diffraction grating region 162, but the present invention is not limited thereto. A plurality of grating regions 107c may be arranged as described in the first example implementation.

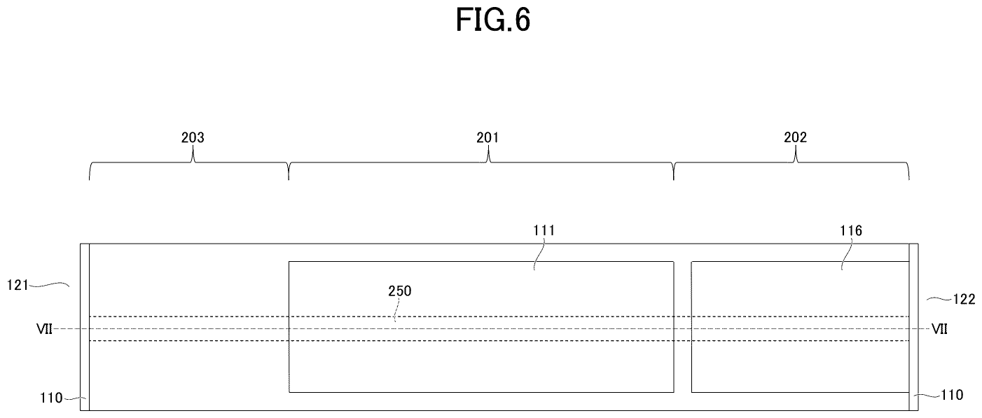

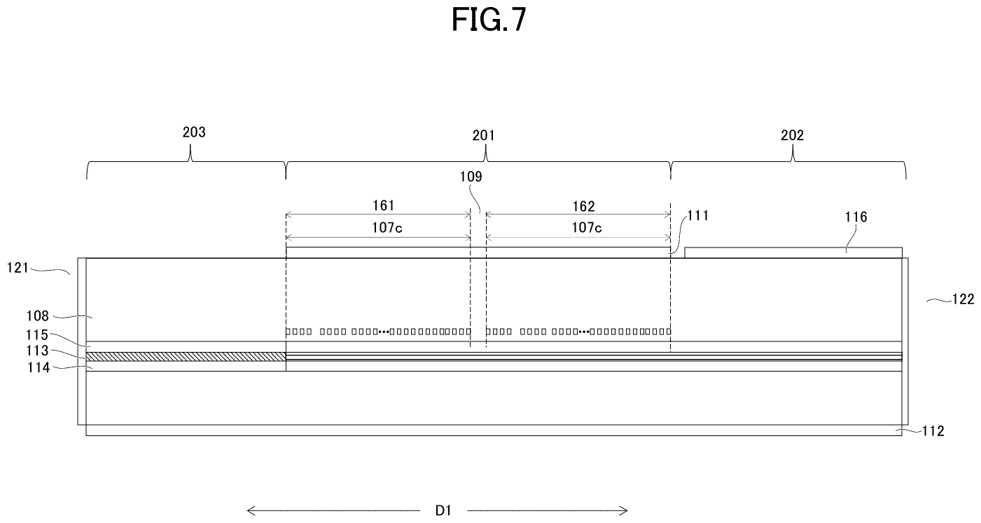

FIG. 6 is a top view of a multi-wavelength laser according to a second example implementation of the present invention. FIG. 7 is a cross-sectional view for schematically illustrating a cross section taken along the line VII-VII of FIG. 6.

The multi-wavelength laser according to the second example implementation may include, in the first direction D1, from the first facet 121 toward the second facet 122, a passive waveguide section 203, a DFB section 201, and an optical amplifier (semiconductor optical amplifier: SOA) section 202. The DFB section 201 has the same structure as that of the multi-wavelength laser described in Modification Example 2 of the first example implementation. Further, those three regions include a waveguide (mesa structure) 250. The shape of the waveguide 250 in top view cannot be observed in plan view because the waveguide 250 is arranged below an electrode to be described later or the like. Accordingly, the shape of the waveguide 250 is indicated by the dotted lines in FIG. 6.

The passive waveguide section 203 may include, on the substrate 101, a passive waveguide lower optical confinement layer 114, a passive waveguide core layer 113, and a passive waveguide upper optical confinement layer 115 in the stated order. On the passive waveguide upper optical confinement layer 115, the second-conductivity-type cladding layer 108 may be arranged. Further, the passive waveguide section 203 may not include a diffraction grating layer 107. The passive waveguide core layer 113 may be formed of a semiconductor layer such as a multiple quantum well (MQW) layer or a bulk that does not absorb light oscillated in the DFB section 201.

A semiconductor multilayer included in the SOA section 202 may have the same structure as that of the DFB section 201 except that no diffraction grating layer 107 is arranged. However, the semiconductor multilayer included in the SOA section 202 may have a structure different from that of the DFB section 201. The SOA section 202 may include an SOA section front surface electrode 116 on the second-conductivity-type cladding layer 108. The SOA section front surface electrode 116 may be formed integrally with the front surface electrode 111 of the DFB section 201. Through injection of a current to the SOA section front surface electrode 116, the output light of the DFB section 201 can be increased. However, the degree of optical amplification of the SOA section 202 is desired to be set to a degree that does not cause a remarkable adverse effect by four-wave mixing.

The wavelength interval of the multi-wavelength laser is determined by Expression (3), and hence the resonator length as the laser is important. With this configuration, the diffraction grating layer 107 does not reach the first facet 121 and the second facet 122, and hence the region in which the diffraction grating layer 107 is formed is determined by a lithography region of the diffraction grating structure. The position accuracy of the lithography region of the diffraction grating structure is sufficiently high, and the resonator length can be formed to a length as designed. For example, in the case of the multi-wavelength laser described in the first example implementation, the positions of the first facet 121 and the second facet 122 substantially match the positions of both ends of the diffraction grating layer. The reason therefore because chipping is performed through cleavage or the like after a plurality of multi-wavelength lasers are formed on a wafer. When the cleavage position is shifted in the first direction D1 in this chipping step, in some cases, the length of the grating region 107a in contact with the first facet 121 and the length of the grating region 107a in contact with the second facet 122 are different from each other. As a result, there is a risk that desired multi-wavelength oscillation cannot be achieved.

A window structure may be arranged between the DFB section 201 and at least one of the first facet 121 and the second facet 122. In the chipping step, even when the lengths of the window structures on the first facet 121 side and the second facet 122 side change, the length of the diffraction grating layer 107 does not change, and hence stable multi-wavelength oscillation can be achieved.

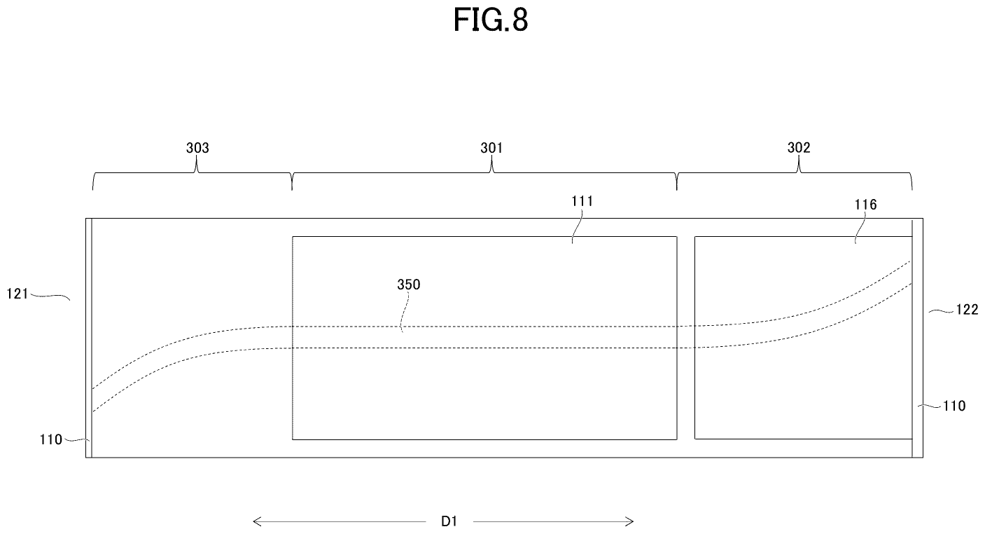

FIG. 8 is a top view of a multi-wavelength laser according to a third example implementation of the present invention. The multi-wavelength laser according to the third example implementation includes, similarly to the second example implementation, a passive waveguide section 303, a DFB section 301, and an optical amplifier section 302. Each of the semiconductor multilayers is the same as that of the second example implementation. The difference from the second example implementation resides in a shape of a waveguide 350 which allows light to propagate therethrough.

The waveguide 350 in the third example implementation is a straight line along the first direction D1 in the DFB section 301, but includes curved portions in the SOA section 302 and the passive waveguide section 303. With this configuration, reflection of light from the first facet 121 and the second facet 122 can be suppressed. The anti-reflection film is formed on each of the first facet 121 and the second facet 122, and hence reflection of light at each facet is sufficiently small. However, it is difficult to reduce the reflection completely to zero. Moreover, the reflected light from the second facet 122 may be amplified by the SOA section 302. When the light reflection by the facet is added to the reflection of light by the diffraction grating structure, there is a risk of oscillation at an unintended wavelength and of affecting the optical output intensity of each wavelength. In the third example implementation, the waveguide 350 between the diffraction grating layer 107 and each facet is bent. Thus, the influence of reflection at each facet can be suppressed, and the multi-wavelength oscillation can be obtained as designed.

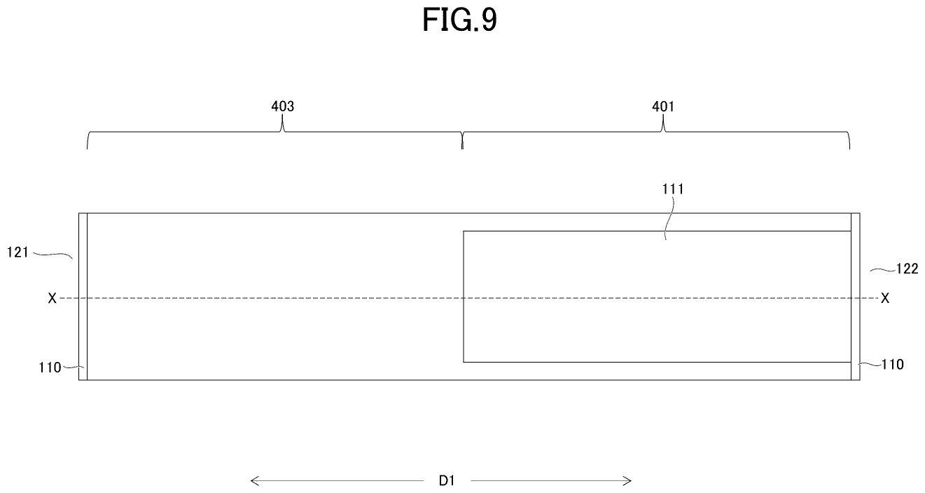

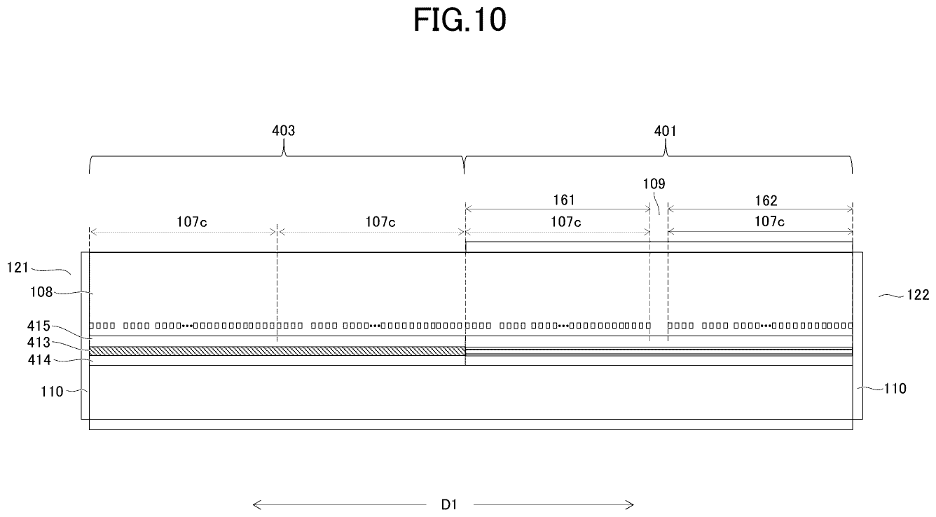

FIG. 9 is a top view of a multi-wavelength laser according to a fourth example implementation of the present invention. FIG. 10 is a cross-sectional view for schematically illustrating a cross section taken along the line X-X of FIG. 9.

In the multi-wavelength laser according to the fourth example implementation, in the first direction D1, from the first facet 121 toward the second facet 122, a DBR section 403 and a DFB section 401 may be arranged side by side. The DFB section 401 may have the same structure as that of the multi-wavelength laser described in Modification Example 2 of the first example implementation.

The DBR section 403 may include, on the substrate 101, a DBR lower optical confinement layer 414, a DBR core layer 413, and a DBR upper optical confinement layer 415 in the stated order. On the DBR upper optical confinement layer 415, the second-conductivity-type cladding layer 108 may be arranged. Further, the DBR section 403 may include the diffraction grating layer 107. The diffraction grating layer 107 included in the DBR section 403 may include two grating regions 107c. Further, no λ/4 phase shift region may be included between the two grating regions 107c.

The operation of the multi-wavelength laser according to the fourth example implementation is described. Similarly to other embodiments, through injection of a current, the DFB section 401 performs multi-wavelength oscillation. In the first example implementation, the anti-reflection film 110 is formed on each of the first facet 121 and the second facet 122. Further, the same structures (the same number of grating regions 107a, 107b, and 107c) are arranged across the phase shift region 109. Accordingly, the optical output intensity output from the first facet 121 and the optical output intensity output from the second facet 122 are theoretically the same. A semiconductor laser used in optical communication generally uses only light output from a facet on one side, and it is desired that the optical output intensity from the facet on one side be large. The multi-wavelength laser according to the fourth example implementation can increase the optical output intensity from the second facet 122 as compared to the multi-wavelength laser according to Modification Example 2 of the first example implementation. In the fourth example implementation, the optical output intensity output from the first facet 121 is decreased. The DBR section 403 is a passive region to which no current is injected, but reflects light to the DFB section 401 side because the grating regions 107c are arranged therein. In the fourth example implementation, the DBR section 403 may include the same grating regions 107c as those of the DFB section 401, and hence can reflect the multi-wavelength light oscillated in the DFB section 401. That is, through reflection of light originally output from the first facet 121 side to the second facet 122 side, the optical output intensity output from the second facet 122 can be increased. The number of grating regions 107c included in the DBR section 403 is not limited to two, and may be one or three or more.

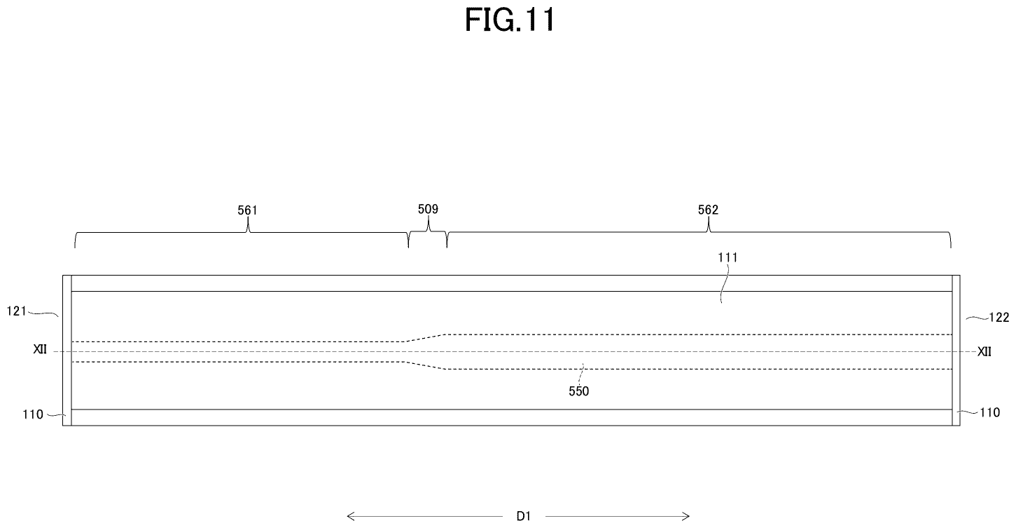

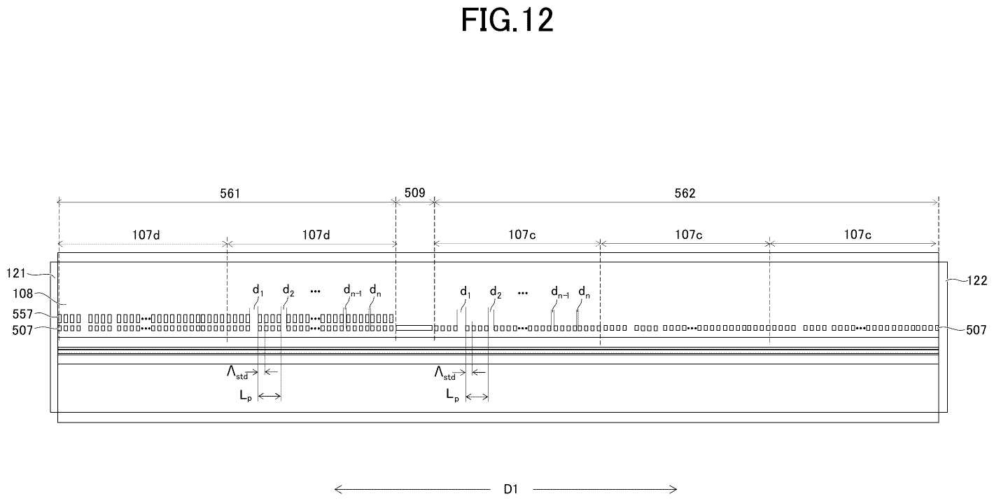

FIG. 11 is a top view of a multi-wavelength laser according to a fifth example implementation of the present invention. FIG. 12 is a cross-sectional view for schematically illustrating a cross section taken along the line XII-XII of FIG. 11. The multi-wavelength laser according to the fifth example implementation may have the same semiconductor multilayer as that of the multi-wavelength laser according to the first example implementation except for a structure of a diffraction grating layer.

The multi-wavelength laser may include, from the first facet 121 side toward the second facet 122 side, in the first direction D1, a first diffraction grating region 561, a phase shift region 509, and a second diffraction grating region 562. The regions may have the same semiconductor multilayer except for the structure of the diffraction grating layer.

In the first diffraction grating region 561, the diffraction grating layer may have a multi-stage structure. In this case, the multi-stage structure may include a first diffraction grating layer 507 and a second diffraction grating layer 557 arranged above the first diffraction grating layer 507. The same material as that of the second-conductivity-type cladding layer 108 may be arranged in a region sandwiched between the first diffraction grating layer 507 and the second diffraction grating layer 557. The position of each unit structure in the second diffraction grating layer may be aligned with the position of each unit structure in the first diffraction grating layer. That is, the diffraction grating period of the first diffraction grating layer 507 and the diffraction grating period of the second diffraction grating layer 557 match each other. Further, the arrangement of grating regions 107d may have the same phase as that of the grating regions 107c in Modification Example 2 of the first example implementation. That is, the uniform diffraction grating region and the phase shift portion may be alternately arranged. The first diffraction grating region 561 may include two grating regions 107d.

In the second diffraction grating region 562, three grating regions 107c which may be each similar to that in Modification Example 2 of the first example implementation may be arranged. In the second diffraction grating region 562, only the first diffraction grating layer 507 may be arranged, and no second diffraction grating layer 557 may be arranged. The second-conductivity-type cladding layer 108 may be arranged in a region of the second diffraction grating region 562 having the same height from the substrate as that of the second diffraction grating layer 557 arranged in the first diffraction grating region 561. The grating region 107c of the second diffraction grating region 562 and the grating region 107d of the first diffraction grating region 561 may be different from each other in the number of diffraction grating layers, but may have the same phase of the diffraction grating structure. That is, the grating region 107c and the grating region 107d may include the same series of unit structures.

The length of the phase shift region 509 in the first direction D1 may be larger than the length of the phase shift region 109, which may have λ/4 phase shift structure, in the first direction D1 in the first example implementation. In the first example implementation, an example in which the phase shift region 109 causes a shift of π as the phase of the diffraction grating may have been described, but the phase shift amount of the phase shift region 109 may be only required to be (2n+1)π (“n” may be an integer of 0 or more), in the fifth example implementation as well. In the fifth example implementation, the length of the phase shift region 509 may be set to be relatively large in order to connect the first diffraction grating region 561 and the second diffraction grating region 562 which may be different from each other in the width of the mesa structure (details thereof may be to be described later).

In the fifth example implementation, the number of diffraction grating layers in the first diffraction grating region 561 is larger than the number of diffraction grating layers in the second diffraction grating region 562, and hence a coupling coefficient κ of light is higher in the first diffraction grating region 561. Accordingly, in the fifth example implementation, the light exiting amount output from the second facet 122 is larger than the light exiting amount output from the first facet 121. Further, similarly to other embodiments, grating structures having the same phase (the same series of unit structures) are included on the front and the rear of the phase shift region 509, and hence the multi-wavelength oscillation is achieved. Further, the number of grating regions included in the first diffraction grating region 561 is different from the number of grating regions included in the second diffraction grating region 562, but, as long as at least one grating region is included in each of the first diffraction grating region 561 and the second diffraction grating region 562, the multi-wavelength oscillation is achieved. The number of diffraction grating layers is not limited to two stages.

In the multi-wavelength laser according to the fifth example implementation, the first diffraction grating region 561 and the second diffraction grating region 562 are different from each other in a width of a mesa structure 550 (mesa width). As illustrated in FIG. 11, the mesa width of the first diffraction grating region 561 is narrower than the mesa width of the second diffraction grating region 562. In addition, the mesa width is smoothly changed in the phase shift region 509. With this structure, the effective refractive index n_{eff} of the first diffraction grating region 561 and the effective refractive index n_{eff} of the second diffraction grating region 562 are caused to match each other. That is, the first diffraction grating region 561 has multi-stages of diffraction grating layers, and hence the effective refractive index n_{eff} of the first diffraction grating region 561 is higher than the effective refractive index n_{eff} of the second diffraction grating region 562. Accordingly, when the mesa width is the same and the drive current is the same throughout the entire region, the wavelength reflected by the grating structure may become different between the first diffraction grating region 561 and the second diffraction grating region 562, resulting in a fear of inhibiting stable multi-wavelength oscillation. In order to avoid this situation, the mesa width is used to adjust the effective refractive index n_{eff} of the first diffraction grating region 561 and the effective refractive index n_{eff} of the second diffraction grating region 562 so that those effective refractive indices n_{eff} become the same.

The present invention is not limited to the example implementations described above, and various modifications may be made thereto. The configuration used to describe the example implementations may be replaced by substantially the same configuration, a configuration having the same action and effect, and a configuration which may achieve the same object. For example, the diffraction grating layer may be arranged between the substrate and the active layer. Further, the grating structures in the second example implementation and the subsequent example implementations may be replaced with the grating region 107a in the first example implementation or the grating region 107b in Modification Example 1.

The present invention relates to a multi-wavelength laser for simultaneously oscillating at a plurality of wavelengths in a DFB laser. The multi-wavelength laser includes an active layer and a diffraction grating layer, and an anti-reflection film formed on each of both facets. The diffraction grating layer includes a λ/4 phase shift region and a grating region including a series of unit structures on each of front and rear of the λ/4 phase shift region in an optical axis direction so that multi-wavelength oscillation is achieved. The series of unit structures have a diffraction grating period that changes gradually or stepwise from a first diffraction grating period to a second diffraction grating period. As another example, in the series of unit structures, a uniform diffraction grating structure and a phase shift portion are alternately arranged, and each phase shift portion varies in phase shift amount. A plurality of grating regions may be arranged between a front facet and the phase shift region and/or between a rear facet and the phase shift region. When a plurality of grating regions are arranged, the grating regions are adjacent to each other. The multi-wavelength laser may include a DFB laser section for performing multi-wavelength oscillation, a passive waveguide section arranged between the DFB laser section and the rear facet, and an optical amplifier section arranged between the DFB laser section and the front facet. The multi-wavelength laser may include, in plan view, a mesa structure which allows light to propagate therethrough, and the mesa structure may be bent with respect to the optical axis in the passive waveguide section and the optical amplifier section. Moreover, the multi-wavelength laser may include a DFB laser section for performing multi-wavelength oscillation, and a DBR section between the DFB laser section and the rear facet. The DBR section includes the same grating region as the grating region included in the DFB laser section. In the multi-wavelength laser, when a region between the λ/4 phase shift region and the rear facet is referred to as a first diffraction grating region and a region between the λ/4 phase shift region and the front facet is referred to as a second diffraction grating region, the number of stages of diffraction grating layers included in the first diffraction grating region and the number of stages of diffraction grating layers included in the second diffraction grating region may be different from each other. For example, the first diffraction grating region may include two stages of diffraction grating layers, and the second diffraction grating region may include one stage of diffraction grating layer. The two stages of diffraction grating layers have the same phase of the series of unit structures, and the grating region of the first diffraction grating region and the grating region of the second diffraction grating region are arranged so as to be the same except for the number of stages of diffraction grating layers. The structure including the DBR section or having the different number of stages of diffraction grating layers is increased in optical output intensity to be output from the front. The multi-wavelength laser has an oscillation wavelength band of a 1.3-μm band, a 1.55-μm band, or other wavelength bands.

While there have been described what are at present considered to be certain embodiments of the invention, it will be understood that various modifications may be made thereto, and it is intended that the appended claims cover all such modifications as fall within the true spirit and scope of the invention.

The foregoing disclosure provides illustration and description, but is not intended to be exhaustive or to limit the implementations to the precise forms disclosed. Modifications and variations may be made in light of the above disclosure or may be acquired from practice of the implementations. Furthermore, any of the implementations described herein may be combined unless the foregoing disclosure expressly provides a reason that one or more implementations may not be combined.

Even though particular combinations of features are recited in the claims and/or disclosed in the specification, these combinations are not intended to limit the disclosure of various implementations. In fact, many of these features may be combined in ways not specifically recited in the claims and/or disclosed in the specification. Although each dependent claim listed below may directly depend on only one claim, the disclosure of various implementations includes each dependent claim in combination with every other claim in the claim set. As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiple of the same item.

No element, act, or instruction used herein should be construed as critical or essential unless explicitly described as such. Also, as used herein, the articles “a” and “an” are intended to include one or more items, and may be used interchangeably with “one or more.” Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, or a combination of related and unrelated items), and may be used interchangeably with “one or more.” Where only one item is intended, the phrase “only one” or similar language is used. Also, as used herein, the terms “has,” “have,” “having,” or the like are intended to be open-ended terms. Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”). Further, spatially relative terms, such as “below,” “lower,” “above,” “upper,” and the like, may be used herein for ease of description to describe one element or feature's relationship to another element(s) or feature(s) as illustrated in the figures. The spatially relative terms are intended to encompass different orientations of the apparatus, device, and/or element in use or operation in addition to the orientation depicted in the figures. The apparatus may be otherwise oriented (rotated 90 degrees or at other orientations) and the spatially relative descriptors used herein may likewise be interpreted accordingly.

What is claimed is:

1. A multi-wavelength laser, comprising:
an active layer; and
a diffraction grating layer including a front diffraction grating region, a rear diffraction grating region, and a phase shift region between the front diffraction grating region and the rear diffraction grating region,
wherein the front diffraction grating region includes one or more grating regions,
wherein each of the one or more grating regions includes a series of unit structures that are different from each other, and
wherein the rear diffraction grating region has the same structure as a structure of the front diffraction grating region.

2. The multi-wavelength laser according to claim 1, wherein the phase shift region has a λ/4 phase shift structure.

3. The multi-wavelength laser according to claim 1, wherein, in each of the one or more grating regions, the series of unit structures have periods which gradually increase or gradually decrease from a first unit structure at one end toward a second unit structure at another end.

4. The multi-wavelength laser according to claim 1, wherein each of the series of unit structures includes a series of sub-unit structures having the same period.

5. The multi-wavelength laser according to claim 1,
wherein, in each of the one or more grating regions, a phase shift portion and a uniform diffraction grating structure included in each of the series of unit structures are alternately arranged, and
wherein the phase shift portion included in each of the series of unit structures varies in phase shift amount.

6. The multi-wavelength laser according to claim 1, further comprising a first facet and a second facet respectively on both sides in a first direction in which the active layer and the diffraction grating layer extend.

7. The multi-wavelength laser according to claim 1, wherein the one or more grating regions are arranged adjacent to each other.

8. The multi-wavelength laser according to claim 6, further comprising:
an optical amplifier section arranged between the front diffraction grating region and the second facet; and
a passive waveguide section arranged between the rear diffraction grating region and the first facet.

9. The multi-wavelength laser according to claim 8, further comprising a waveguide which allows light to propagate therethrough,
wherein, in plan view, the waveguide is bent with respect to the first direction in the passive waveguide section and the optical amplifier section.

10. The multi-wavelength laser according to claim 6, further comprising a DBR section including the diffraction grating layer, the DBR section being arranged between the rear diffraction grating region and the first facet.

11. The multi-wavelength laser according to claim 1,
wherein, in the rear diffraction grating region, the diffraction grating layer has a multi-stage structure including a first diffraction grating layer and a second diffraction grating layer, and
wherein a position of each of the series of unit structures in the second diffraction grating layer is aligned with a position of each of the series of unit structures in the first diffraction grating layer.

12. The multi-wavelength laser according to claim 11, further comprising a waveguide which allows light to propagate therethrough,
wherein, in plan view, in a second direction perpendicular to a first direction in which the active layer and the diffraction grating layer extend, a width of the waveguide in the front diffraction grating region is larger than a width of the waveguide in the rear diffraction grating region.

13. The multi-wavelength laser according to claim 1, further comprising an electrode provided across the front diffraction grating region, the rear diffraction grating region, and the phase shift region.

14. The multi-wavelength laser according to claim 6, further comprising an anti-reflection film formed on each of the first facet and the second facet.
